(19) United States
(12) Patent Application Publication
(10) Pub. No.: US 2023/0328945 A1
(43) Pub. Date: Oct. 12, 2023

(54) HOLDING MECHANISM AND DEVICE INCLUDING THE SAME

(71) Applicant: FUJIFILM Business Innovation Corp., Tokyo (JP)

(72) Inventor: Kota SATO, Kanagawa (JP)

(73) Assignee: FUJIFILM Business Innovation Corp., Tokyo (JP)

(21) Appl. No.: 17/869,769

(22) Filed: Jul. 20, 2022

(30) Foreign Application Priority Data
Mar. 23, 2022 (JP) 2022-046655

(51) Int. Cl. H05K 13/00

(52) U.S. Cl. CPC H05K 13/0069; B41J 29/38

(57) ABSTRACT

A holding mechanism includes a body having a conduction portion, and a mounting portion on which a mounting body having an end part provided with a conduction portion capable of facing the conduction portion is mounted; a holding member that is provided on the body and has a holding portion displaced between a holding position where the holding portion comes into contact with an end part of the mounting body to hold the end part and a non-holding position where the holding portion avoids the end part not to hold the end part; and a conductive elastic member that is installed between at least the conduction portion of the body and the holding portion at least at the holding position. The end part of the mounting body including the conduction portion at the end part is interposed and held between the holding portion at the holding position and the elastic member in an elastically deformed state.

### CROSS-REFERENCE TO RELATED APPLICATIONS

This application is based on and claims priority under 35 USC 119 from Japanese Patent Application No. 2022-046655 filed Mar. 23, 2022.

### BACKGROUND

### (i) Technical Field

The present invention relates to a holding mechanism and a device including the holding mechanism.

### (ii) Related Art

The following JP2009-141057A (Claim 1, Paragraph 0021, and FIGS. 1 to 5) describes a structure including a housing provided with an opening portion, a lid attachably and detachably disposed in the opening portion, a slot provided in a substrate disposed in the housing, and a conduction member that conducts electricity between the substrate provided with the slot and the lid to each other.

The following JP2007-304447A (Claim 1, Paragraph 0027, and FIGS. 1 to 4) describes a conduction mechanism of an image forming device in which a unit member comprising a power supply required portion can be attachably and detachably mounted on the device body, and in a case where the unit member is mounted, a predetermined contact portion of a power supply substrate of the device body and a contact portion of the power supply required portion can conduct electricity therebetween via the conduction member.

Additionally, regarding the conduction mechanism, JP2007-304447A (Claim 1, Paragraph 0027, and FIGS. 1 to 4) describes that the conduction member consists of a two-stage conductive compression coil spring in which a larger-diameter portion and a smaller-diameter portion are connected to each other, a circular hole having a diameter larger than the smaller-diameter portion of the coil spring and smaller than the larger-diameter portion is formed in a frame portion of the device body, the smaller-diameter portion of the coil spring is inserted through the circular hole so as to protrude toward a mounting portion side of the unit member, and the larger-diameter portion is resiliently mounted between the frame portion and the contact portion of the power supply substrate in a compressed state.

### SUMMARY

Aspects of non-limiting embodiments of the present disclosure relate to a holding mechanism and a device including the same that conduction between a body and a mounting body is stable even in a case where vibration is received, in a case where the body having a conduction portion is mounted with the mounting body having an end part provided with a conduction portion capable of facing the conduction portion of the body, compared to a case where the holding mechanism is not a mechanism that interposes and holds the end part of the mounting body including the conduction portion at the end part between a holding portion of a holding member at a holding position in the body and an elastic member in an elastically deformed state.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a body having a conduction portion, and a mounting portion on which a mounting body having an end part provided with a conduction portion capable of facing the conduction portion is mounted; a holding member that is provided on the body and has a holding portion displaced between a holding position where the holding portion comes into contact with an end part of the mounting body to hold the end part and a non-holding position where the holding portion avoids the end part not to hold the end part; and a conductive elastic member that is installed between at least the conduction portion of the body and the holding portion at least at the holding position. The end part of the mounting body including the conduction portion at the end part is interposed and held between the holding portion at the holding position and the elastic member in an elastically deformed state.

### BRIEF DESCRIPTION OF THE DRAWINGS

Exemplary embodiment(s) of the present invention will be described in detail based on the following figures, wherein:

FIG. 1 is a perspective view of a holding mechanism according to Exemplary Embodiment 1;

FIG. 2A is a plan view of the holding mechanism, FIG. 2B is a partial cross-sectional view taken along line B-B of FIG. 2A, and FIG. 2C is a partial cross-sectional view taken along line C-C of FIG. 2A;

FIG. 3A is a partial cross-sectional view of a portion circled by a broken line in FIG. 2B, and FIG. 3B is a partial cross-sectional view of a portion circled by a broken line in FIG. 2C;

FIG. 4A is a plan view of a body of the holding mechanism and a mounting body mounted on the body, and FIG. 4B is a partial cross-sectional view of the body along line B-B;

FIG. 5A is a plan view of the body in a case where a holding portion of the holding mechanism is at a non-holding position, and FIG. 5B is a partial cross-sectional view of the body along line B-B;

FIG. 6A is a perspective view of a holding member of the holding mechanism, and FIG. 6B is a side view and a plan view of the holding member and an elastic member in three directions;

FIG. 7A is a perspective view in a case where the mounting body of the holding mechanism is held or removed, and FIG. 7B is a partial cross-sectional view of the holding member and a peripheral portion thereof in the holding mechanism of FIG. 7A;

FIG. 8A is a partial cross-sectional view of a displacement guide portion and a peripheral portion thereof in the holding mechanism, and FIG. 8B is a partial cross-sectional view showing the state of action of the displacement guide portion in FIG. 8A;

FIG. 9A is a partial cross-sectional view of a pressing guide portion and a peripheral portion thereof in the holding mechanism, and FIG. 9B is a partial cross-sectional view showing a state of action of the pressing guide portion in FIG. 9A;

FIG. 10A is a plan view and a side view of the holding member at a holding position and the non-holding position in a modification example of Exemplary Embodiment 1, and FIG. 10B is a partial cross-sectional view showing a holding state by the holding member in FIG. 10A;

FIG. 11A is a partial cross-sectional view in the holding state of the holding mechanism according to Exemplary Embodiment 2, and FIG. 11B is a partial cross-sectional view showing a state in which the mounting body is mounted by the holding mechanism in FIG. 11A;

FIG. 12A is a side view of the holding member and the elastic member in the holding mechanism of FIGS. 11A and 11B, and FIG. 12B is a side view showing a state in which the holding member of FIGS. 11A and 11B are displaced between the holding position and the non-holding position;

FIG. 13A is a plan view of the holding mechanism of FIGS. 11A and 11B in a case where the mounting body is mounted, and FIG. 13B is a partial cross-sectional view of the state of FIG. 13A;

FIG. 14A is a partial cross-sectional view of the holding state in the modification example of Exemplary Embodiment 2, and FIG. 14B is a partial cross-sectional view of the mounting body in the modification example of FIG. 14A;

FIG. 15A is a side view of the holding member and the elastic member in the modification example of Exemplary Embodiment 3, and FIG. 15B is a side view showing a state in which the holding member of FIG. 15A is displaced between the holding position and the non-holding position;

FIG. 16 is a schematic view of a device including the holding mechanism according to Exemplary Embodiment 3; and

FIG. 17A is a partial cross-sectional view of another configuration example of the holding mechanism, and FIG. 17B is a plan view of an elastic member, having conductivity, applied by the holding mechanism of FIG. 17A.

### DETAILED DESCRIPTION

Hereinafter, exemplary embodiments for carrying out the present invention will be described with reference to the drawings.

### Exemplary Embodiment 1

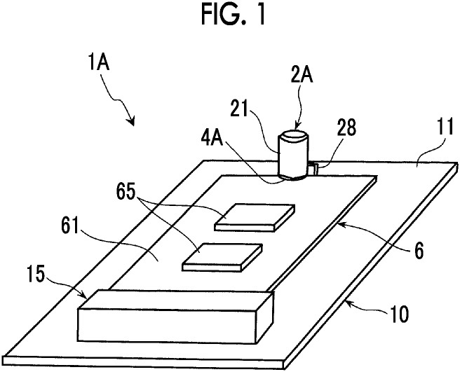

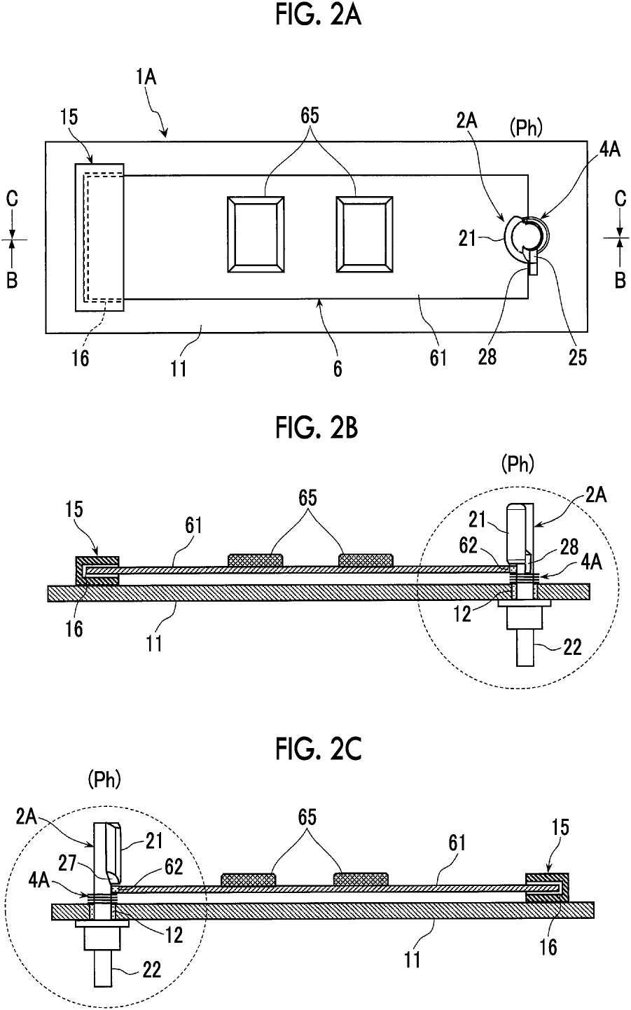

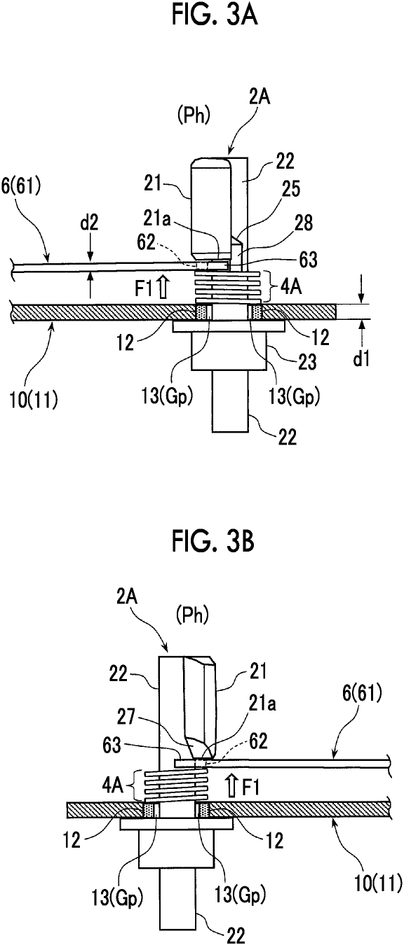

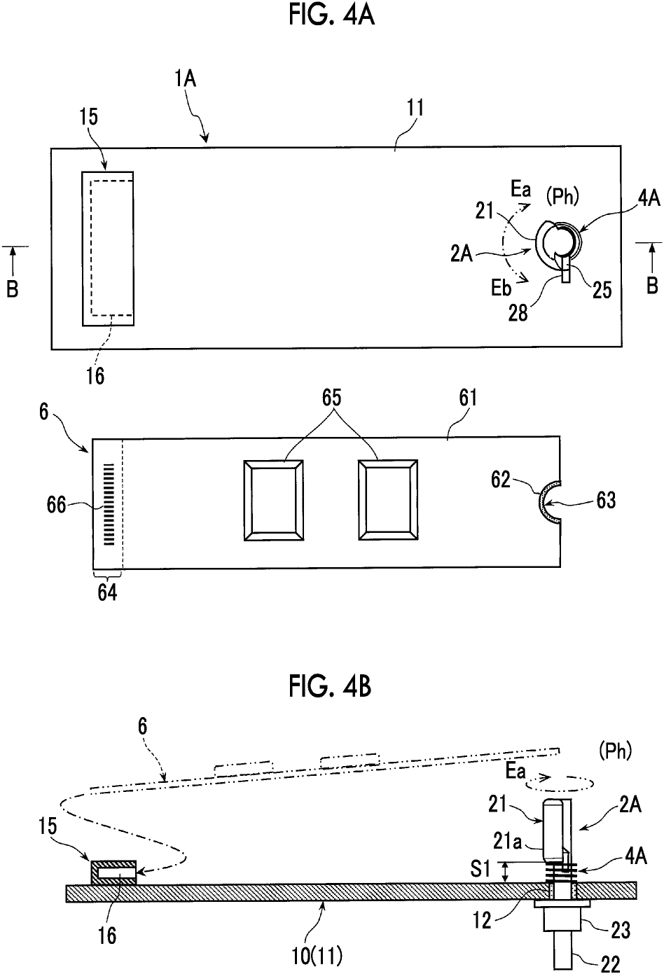

FIG. 1 is a perspective view of a holding mechanism 1A according to Exemplary Embodiment 1 of the present invention. FIGS. 2A to 2C are a plan view of the holding mechanism 1A and a partial cross-sectional view taken along line B-B of the holding mechanism 1A, and a partial cross-sectional view taken along line C-C. FIGS. 3A and 3B are partial cross-sectional views of portions circled by respective broken lines in FIGS. 2B and 2C. FIGS. 4A and 4B are a plan view of a body and the like in the holding mechanism 1A and a mounting body mounted on the body, and a partial cross-sectional view of the body along line B-B.

As shown in FIG. 1 to FIG. 4B, and the like, the holding mechanism 1A comprises a body 10, a holding member 2A, and an elastic member 4A.

Among these, the body 10 is a structure having a portion on which a mounting body 6 is mounted. The body 10 is a structure having a conduction portion 12, and a mounting portion 15 on which the mounting body 6 having an end part 63 provided with a conduction portion 62 capable of facing the conduction portion 12 is mounted.

As shown in FIG. 1 to FIG. 4B, and the like, the body 10 in Exemplary Embodiment 1 is constituted of a plate-shaped member 11. The body 10 is not limited to this plate-shaped form, and may consist of any form as long as the body 10 has a portion on which the mounting body 6 is mounted.

The conduction portion 12 is a portion for establishing conduction with a conduction portion 62 of the mounting body 6 for power supply, securing of ground potential, and the like.

As shown in FIGS. 3A and 3B, the conduction portion 12 in Exemplary Embodiment 1 is provided around an attachment hole 13 of the holding member 2A provided in the plate-shaped member 11 of the body 10. The conduction portion 12 is formed in an annular form consisting of a required width along the circular hole shape of the attachment hole 13. Additionally, as shown in FIGS. 3A to 3C and FIGS. 2B and 2C, the conduction portion 12 is provided in a state of being exposed to both the front and back surfaces of the plate-shaped member 11 around the attachment hole 13 of the holding member.

The conduction portion 12 is formed by using a material having conductivity, such as metal. For example, in a case where the plate-shaped member 11 is a printed board, the conduction portion 12 may be an electrode portion formed so as to be exposed to the outside. In addition, the conduction portion 12 may be formed so as to be exposed to at least the surface of the body 10 on the side where the holding member 2A and the elastic member 4A are present.

The mounting portion 15 is a portion of the body 10 for mounting the mounting body 6.

For example, in a case where the mounting body 6 is a plate-shaped printed board 61, the mounting portion 15 is constituted of a slot connector into which an insertion end part 64 of the printed board 61 is inserted. The mounting portion 15 consisting of a slot connector is provided with an insertion recess 16 into which the insertion end part 64 of the printed board 61 is inserted.

Additionally, the mounting portion 15 consisting of the slot connector is configured to mount the mounting body 6 made of the printed board 61 in a state in which the mounting body 6 is kept substantially parallel to the surface of the plate-shaped member 11 of the body 10. In other words, the mounting portion 15 is installed such that the insertion recess 16 is brought into a state of being substantially parallel to the surface of the plate-shaped member 11.

On the other hand, the mounting body 6 is a structure that is mounted on the body 10 and is required to be electrically connected to the conduction portion 12 of the body 10. As shown in a lower portion of FIG. 4A, the mounting body 6 has an end part 63 provided with the conduction portion 62 capable of facing the conduction portion 12 of the body 10 in a case where the mounting body 6 is mounted on the body 10.

The mounting body 6 in Exemplary Embodiment 1 is configured as the printed board 61 on which an electronic component 65 including an integrated circuit or the like is mounted.

The end part 63 of the mounting body 6 is an end part that is provided with the conduction portion 62 and serves as a target held by the holding portion 21 of the holding member 2A. Additionally, the end part 63 is provided at the end part opposite to a portion (insertion end part 64) mounted on the mounting portion 15 of the body 10, but the holding by the holding member 2A is effective. For example, the end part 63 may be provided in addition to or independently of end parts in the other portions. As shown in the lower portion of FIG. 4A, the end part 63 in Exemplary Embodiment 1 is a plate-shaped portion and is formed as a depressed end part cut out in a semicircular shape.

The conduction portion 62 in the mounting body 6 is formed in a semi-annular form consisting of a predetermined width along a semicircular depressed shape of the depressed end part 63. Additionally, as shown in FIGS. 2B and 2C, the conduction portion 62 is provided so as to be exposed on both the front and back surfaces of the depressed end part 63 of the printed board 61. Moreover, the conduction portion 62 is formed of a material having conductivity, such as metal. In addition, the conduction portion 62 may be provided so as to be exposed to at least the surface of the mounting body 6 facing the conduction portion 12 of the body 10 in a case where the conduction portion 62 is mounted on the body 10.

Additionally, in the mounting body 6 consisting of the printed board 61, as shown in the lower portion of FIG. 4A, the insertion end part 64 inserted into the insertion recess 16 of the slot connector of the mounting portion 15 is provided with a connection terminal 66 for transmitting a signal or the like between the mounting body 6 and the body 10.

Next, the holding member 2A is a member that holds the end part 63 of the mounting body 6. As shown in FIGS. 2A to 2C, FIGS. 4A and 4B, FIGS. 5A and 5B, and the like, the holding member 2A has the holding portion 21 that is displaced between a holding position Ph where the holding portion 21 comes into contact with the end part 63 of the mounting body 6 to hold the end part 63 and a non-holding position Pf where the holding portions 21 avoids the end part 63 not to hold the end part 63.

As shown in FIGS. 4A and 4B, 5A and 5B, 6A and 6B, and the like, the holding member 2A in Exemplary Embodiment 1 has a strut portion 22 that supports the holding portion 21, and is configured as a member that is displaced between the holding position Ph and the non-holding position Pf as the holding portion 21 rotates around the strut portion 22. Additionally, the holding member 2A is provided such that the holding portion 21 is fixed to the strut portion 22, and the strut portion 22 is rotatably attached to the body 10.

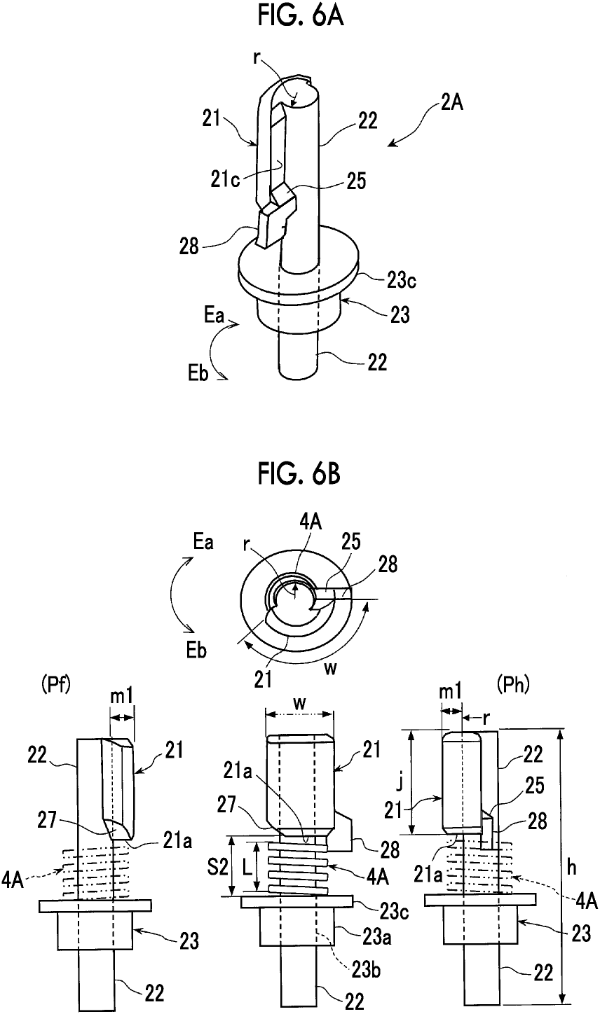

The holding portion 21 is a portion capable of at least coming into contact with and holding the end part 63 having the conduction portion 62 of the mounting body 6 mounted on the body 10. As shown in FIGS. 6A and 6B, the holding portion 21 is configured as, for example, a portion consisting of a shape protruding outward by a required protrusion amount m1 from a part of an upper side surface of the strut portion 22.

The strut portion 22 is a portion capable of supporting the holding portion 21. As shown in FIGS. 6A and 6B, the strut portion 22 is constituted of, for example, a columnar member consisting of required diameter r and length h.

Additionally, as shown in FIGS. 6A and 6B, the holding portion 21 is configured as a portion consisting of a shape in which the holding portion 21 protrudes by the required protrusion amount m1 outward in the direction of a radius r from a part of the upper side surface with respect to the columnar strut portion 22. In this case, the entire holding portion 21 is formed as a plate-shaped structural portion that is curved along a side surface of the strut portion 22 with a width w of a curved surface narrower than the length of half of the peripheral length of the side surface of the strut portion 22 and protrudes with a height j and a thickness of the protrusion amount m1.

Moreover, the holding portion 21 has a holding surface 21a that faces the surface of the body 10 at a spacing and consists of a face substantially parallel to the surface.

Such a holding portion 21 is provided in a state of being integrally molded with and fixed to the strut portion 22, or is provided by fixing a body formed separately from the strut portion 22 to the strut portion 22.

Also, the holding member 2A is provided on the body 10 as follows, for example.

That is, the holding member 2A is provided by inserting a lower portion of the strut portion 22 into the attachment hole 13 provided in the body 10 to pass a part thereof through the attachment hole, and then attaching a spacing maintaining portion 23 to a portion (a portion present on a side opposite to the holding portion 21 across the body 10) of the strut portion 22 protruding from the attachment hole 13. In this case, the holding member 2A is provided in such a posture that the holding portion 21 faces the mounting portion 15. Additionally, in this case, the spacing maintaining portion 23 is fixed to the strut portion 22 and is not fixed to the body 10.

Additionally, the holding member 2A provided in the body 10 is attached such that the strut portion 22 thereof is rotatable with respect to the attachment hole 13 of the body 10. Accordingly, the holding member 2A can be moved such that the holding portion 21 thereof rotates optionally and integrally with the strut portion 22 (including the spacing maintaining portion 23 in the present example) with respect to the body 10 around the strut portion 22.

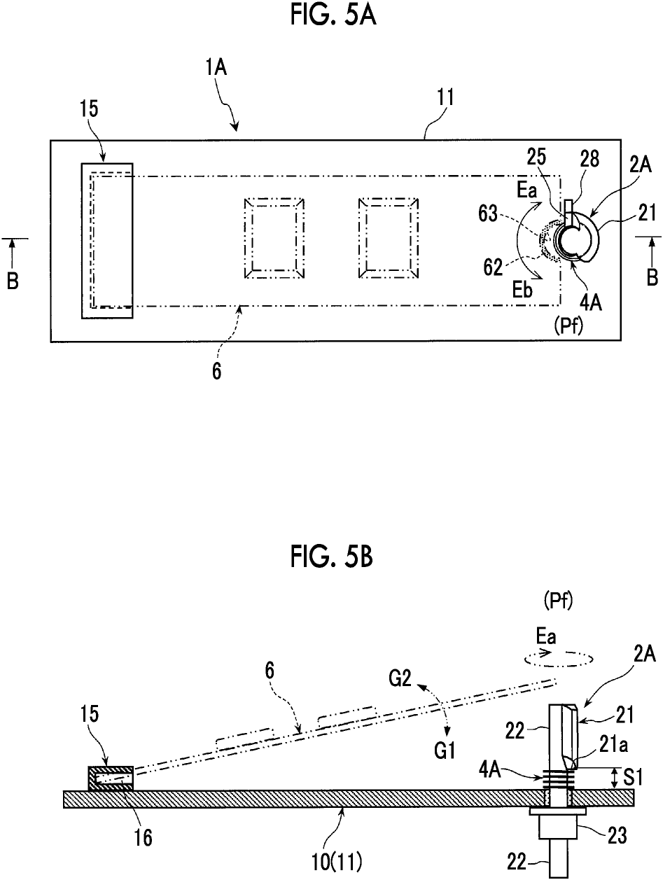

As shown in FIGS. 4A and 4B, FIGS. 5A and 5B, and the like, the spacing maintaining portion 23 is a portion that maintains, at a required dimension, a spacing S1 between the holding surface 21a of the holding portion 21 and the surface of the body 10 in a case where the mounting body 6 is not held. As shown in FIGS. 6A and 6B, the spacing maintaining portion 23 is constituted of, for example, a member in a form consisting of a body portion 23a provided with a mounting hole 23b through which the strut portion 22 is fitted and penetrated, and an upper end flange portion 23c provided at an upper end of the body portion 23a. The spacing maintaining portion 23 may be constituted of a member in a form having no upper end flange portion 23c as long as the body portion 23a has a dimension larger than the opening of the attachment hole 13 in the body 10.

As shown in FIG. 6B, the spacing S1 is a value smaller than a spacing S2 between the holding surface 21a of the holding portion 21 and the upper end flange portion 23c of the spacing maintaining portion 23 in a case where the body 10 is excluded by the amount excluding a thickness d1 of the body 10 (refer to FIG. 3A) (S1≈S2 - d1).

Moreover, the holding member 2A is configured as a member having conductive or a (non-conductive) member having no conductivity. For this reason, there is a case where the holding member 2A is configured such that the whole or a part thereof has conductivity, or there is a case where the holding member 2A is configured such that the whole thereof is non-conductive.

The holding member 2A in Exemplary Embodiment 1 is configured as a member in which at least a surface layer portion or the whole of each of the holding portion 21 and the strut portion 22 has conductivity. Additionally, in the holding member 2A, the spacing maintaining portion 23 is also configured as a conductive member.

Next, as shown in FIG. 2A to FIG. 4B, and the like, the elastic member 4A is an elastic member having conductivity, which is installed between at least the conduction portion 12 of the body 10 and the holding portion 21 at least at the holding position Ph.

The elastic member 4A in Exemplary Embodiment 1 is configured as a coil spring.

The coil spring as the elastic member 4A is a coil spring consisting of a required length L, coil inner and outer diameters, and a spring constant, and a coil spring made of a material having conductivity or with conductivity is applied.

The conductivity of the elastic member 4A may be such conductivity that the conduction performance required between the body 10 and the mounting body 6 is obtained in a case where the conduction portion 12 of the body 10 and the conduction portion 62 of the mounting body 6 come into contact with each other.

Additionally, the coil inner diameter of the coil spring may be a dimension that can ensure a situation in which the coil spring can be compressed and elastically deformed around the strut portion 22. For this reason, the coil inner diameter is set to, for example, a dimension larger than the diameter of the strut portion 22 in the holding member 2A.

Additionally, the coil outer diameter (including the thickness of the coil wire) of the coil spring may be such a dimension that can satisfy a relationship in which, in a case where the mounting body 6 is held, an upper end part of the coil spring comes into contact with the holding surface 21a of the holding portion 21 in the holding member 2A and the conduction portion 12 of the body 10 and a lower end part of the coil spring comes into contact with the conduction portion 62 of the mounting body 6.

Additionally, as shown in FIG. 6B, the elastic member 4A consisting of the coil spring is installed in a state in which a coil portion is fitted into the strut portion 22 of the holding member 2A from the outside thereof. Additionally, in a case where the installation of the elastic member 4A consisting of the coil spring is expressed from the viewpoint of the holding member 2A, as shown in FIGS. 3A to 3C and FIGS. 4A and 4B, the above-described holding member 2A is present in the coil of the coil spring of the elastic member 4A and is installed so that the holding portion 21 is capable of coming into contact with a part of the coil spring. Accordingly, the elastic member 4A is held by the holding member 2A, and it is not necessary to separately prepare means (holding member, holder, or the like) for holding the elastic member 4A.

The elastic member 4A consisting of the coil spring is provided on the body 10 as follows, for example.

That is, the elastic member 4A is provided on the body 10 by inserting the lower portion of the strut portion 22 into the attachment hole 13 of the body 10 to pass a part thereof through the attachment hole, with the strut portion 22 of the holding member 2A fitted in the coil of the coil spring, and then performing the attachment work of the holding member 2A as described above.

Additionally, in the elastic member 4A provided on the body 10, in a case where the spacing S1 between the holding surface 21a of the holding portion 21 in the holding member 2A and the surface of the body 10 is set to the same dimension as a length (free length) L of the coil spring or a dimension longer than the length L, as shown in FIG. 4B, one end part (for example, the lower end part) of the coil spring is in the state of being coming into contact with the conduction portion 12 of the body 10, while the other end part (for example, the upper end part) of the coil spring is brought into a state of having come into contact with the holding surface 21a of the holding portion 21.

In this case, the holding member 2A is supported by the elastic member 4A such that the spacing between the holding surface 21a of the holding portion 21 and the surface of the body 10 is maintained at the spacing S1.

Then, the holding mechanism 1A is assembled by attaching the holding member 2A and the conductive elastic member 4A to the body 10.

As shown in FIGS. 4A and 4B, FIGS. 5A and 5B, and the like, the assembled holding mechanism 1A is a mechanism that can move the holding member 2A such that the holding portion 21 rotates around the strut portion 22 in a directions indicated by arrows Ea and Eb.

Additionally, in the holding mechanism 1A, as shown in FIGS. 2A to 2C, FIGS. 4A and 4B, and the like, a position where the holding portion 21 faces the mounting portion 15 in the body 10 is configured as the holding position Ph, and as shown in FIGS. 5A and 5B, a position where the holding portion 21 does not face the mounting portion 15 in the body 10 is configured as the non-holding position Pf.

The holding member 2A is rotated and displaced such that the holding portion 21 is present at the non-holding position Pf while the mounting body 6 is mounted and held on the body 10 and in a case where the mounting body 6 is removed from the body 10.

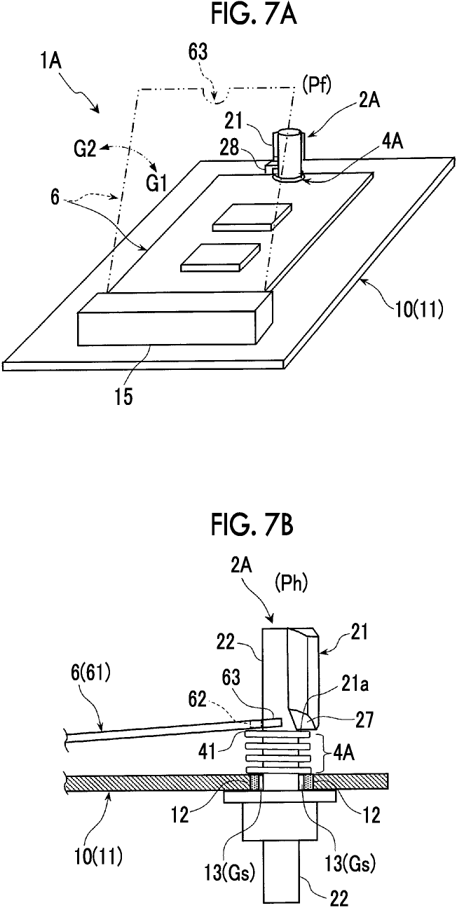

Additionally, in the holding mechanism 1A, as shown in FIG. 5B, FIG. 7B, and the like, in a case where the holding portion 21 is at the non-holding position Pf, a part (for example, a portion present on a side closer to the mounting portion 15) of the elastic member 4A is disposed so as to be present between the holding portion 21 and the body 10 in a case where the part is assumed to be at the holding position Ph.

In other words, in the holding mechanism 1A, in a case where the holding portion 21 is at the non-holding position Pf, a part of the elastic member 4A is installed so as to be present below the holding portion 21 in a case where the part is assumed to be at the holding position Ph.

Moreover, in the holding mechanism 1A, as shown in FIG. 5B, FIG. 7B, and the like, in a case where the holding portion 21 is at the non-holding position Pf, another part (for example, a portion located on a side far from the mounting portion 15 or on a side opposite to the mounting portion 15 across the strut portion 22 interposed therebetween) of the elastic member 4A is disposed so as to be present between the holding portion 21 at the non-holding position Pf and the body 10.

In Exemplary Embodiment 1, in a case where the holding portion 21 is at the non-holding position Pf, the other part of the elastic member 4A is installed so as to be brought into a state of having come into contact with the holding surface 21a of the holding portion 21 at the non-holding position Pf (in this case, so as to be brought into a state of coming into contact with the body 10).

### Mounting and Holding of Mounting Body

In the holding mechanism 1A consisting of the above configuration, the mounting body 6 is mounted and held as follows.

First, in the holding mechanism 1A, the holding member 2A is rotated to displace the holding portion 21 so as to be present at the non-holding position Pf as shown in FIGS. 5A and 5B and FIGS. 7A and 7B. The operation of the displacement to the non-holding position Pf is performed by manual work. The manual work is the work of pinching and rotating the holding member 2A with fingers.

Accordingly, in the holding mechanism 1A, the holding portion 21 of the holding member 2A is brought into a state of being not present at the holding position Ph. In this case, the non-holding position Pf of the holding portion 21 is a position where the holding portion does not interfere with the movement path of the end part 63 of the mounting body 6 in a case where the holding portion 21 is mounted.

Additionally, in this case, due to the displacement of the holding portion 21 to the non-holding position Pf, in the holding mechanism 1A, as shown in FIG. 5B and FIG. 7B, a part of the elastic member 4A (particularly a part of an upper end of the coil spring) hidden from above by the holding portion 21 at the holding position Ph is brought into a state of having been exposed upward toward a lateral side of the strut portion 22.

Subsequently, with respect to the mounting body 6 to be mounted, as illustrated by two-dot chain lines in FIG. 5B, the insertion end part 64 is inserted into the insertion recess 16 of the mounting portion 15 in the body 10 to be in a slightly inclined state, and then, a portion on a side with the end part 63 having the conduction portion 62 is moved in a direction indicated by an arrow G1 so as to approach the holding member 2A of the body 10.

In addition, the operation of displacement of the holding portion 21 to the non-holding position Pf may be performed in cooperation with the operation in a case where the mounting body 6 is mounted on the mounting portion 15 and moved in the direction indicated by the arrow G1.

Accordingly, as shown in FIG. 7B, the mounting body 6 is moved such that the end part 63 having the conduction portion 62 approaches the strut portion 22 of the holding member 2A and the end part 63 thereof comes into contact with the portion of the coil spring of the elastic member 4A that is exposed toward an upper side of the upper end part 41 including the conduction portion 62. In this case, since the end part 63 of the mounting body 6 is a semicircular depressed end part, the end part 63 is moved so as to be guided by the columnar strut portion 22 of the holding member 2A and is accurately moved to a position where the end part 63 is held by the holding member 2A.

Additionally, in a case where the portion of the mounting body 6 with the end part 63 is moved toward the body 10 so as to be further pushed down after this contact, the coil spring of the elastic member 4A is elastically deformed so as to be compressed by being pushed by the end part 63.

For this reason, in the holding mechanism 1A, it is possible to bring the end part 63 of the mounting body 6 into contact with a part of the elastic member 4A in conjunction with the operation in a case where the mounting body 6 is mounted on the body 10, to elastically deform the elastic member 4A. Additionally, the mounting body 6 is brought into a state in which the insertion end part 64 thereof is completely inserted into and connected to the insertion recess 16 of the mounting portion 15 by the above-described movement operation of the mounting body 6.

Subsequently, in the holding mechanism 1A, the holding member 2A is rotated to displace the holding portion 21 so as to be present at the holding position Ph as shown in FIGS. 2A to 2C and FIGS. 3A and 3B. The operation of the displacement to the holding position Ph is also performed by manual work.

Accordingly, in the holding mechanism 1A, as shown in FIGS. 2A to 2C, the holding portion 21 of the holding member 2A rides on the end part 63 of the mounting body 6 via the holding surface 21a to come into contact with the end part 63, and is displaced to the holding position Ph. In this case, the coil spring of the elastic member 4A is placed in a compressed and elastically deformed state below the end part 63 of the mounting body 6.

As a result, the mounting body 6 is mounted on the body 10 as shown in FIG. 1 and the like.

Additionally, in this case, as shown in FIGS. 2A to 2C, FIGS. 3A and 3B, and the like, the holding mechanism 1A interposes and holds the end part 63 of the mounting body 6 including the conduction portion 62 at the end part 63 between the holding portion 21 at the holding position Ph of the holding member 2A and the elastic member 4A in the elastically deformed state.

Additionally, as shown in FIG. 2B, FIG. 2C, and the like, the mounting body 6 held by the holding mechanism 1A is mounted on the body 10 in a state in which the entire mounting body (printed board 61) is substantially parallel to the surface of the body 10.

Then, as shown in FIGS. 3A and 3B, and the like, the elastic member 4A in the elastically deformed state in a case where the elastic member is held is brought into a state in which at least a part of the lower end part thereof is brought into a state of having come into contact with a part of the conduction portion 12 of the body 10, while at least a part of the upper end part thereof is brought into a state of having come into contact with a part of the conduction portion 62 of the mounting body 6.

Accordingly, the mounting body 6 is brought into a state in which the mounting body 6 and the body 10 are connected to each other in an energizable manner via the conduction portion 62, the conductive elastic member 4A, and the conduction portion 12.

Additionally, as shown in FIGS. 3A and 3B, the end part 63 of the mounted mounting body 6 including the conduction portion 62 receives a force F1 caused by the restoring force of the elastic member 4A after elastic deformation, and is maintained in the state of being elastically pressed toward (the holding surface 21a of) the holding portion 21 of the holding member 2A. The force F1 is a spring force generated depending on the amount of compression and elastic deformation of the elastic member 4A in a case where the mounting body 6 is mounted.

Therefore, according to the holding mechanism 1A, the conductive elastic member 4A in the elastically deformed state connects the conduction portion 12 and the conduction portion 62 to each other in a conductable manner, and elastically presses the end part 63 of the mounting body 6 against the holding portion 21 of the holding member 2A. Thus, the conduction between the body 10 and the mounting body 6 is stable even in a case where vibration is received.

Additionally, in the holding mechanism 1A, as shown in FIG. 4B and the like, a part of the conductive elastic member 4A is disposed so as to face (the holding surface 21a of) of the holding portion 21 at the holding position Ph of the holding member 2A.

For this reason, according to the holding mechanism 1A, compared to a case where the conductive elastic member 4A is disposed at a position that does not face (the holding surface 21a of) the holding portion 21 of the holding member 2A (a position in contact with a portion separated from the end part 63 of the mounting body 6), the force F1 caused by the restoring force of the elastic member 4A in the elastically deformed state is less likely to reach the portion separated from the end part 63 of the mounting body 6. As a result, in the holding mechanism 1A, the conduction between the body 10 and the mounting body 6 may be stabilized while avoiding the occurrence of deformation of the mounting body 6 resulting from the load of the force F1 being applied to the portion separated from the end part 63 of the mounting body 6.

Additionally, in the holding mechanism 1A, at least the surface layer portion or the whole of each of the holding portion 21, the strut portion 22, and the spacing maintaining portion 23 of the holding member 2A is configured as a member having conductivity.

For this reason, according to the holding mechanism 1A, in a case where the holding member 2A having conductivity is installed such that the strut portion 22 and the spacing maintaining portion 23 are brought into a state of having come into contact with the conduction portion 12 of the body 10, and the holding surface 21a or the like of the holding portion 21 is brought into a state in which the holding surface is capable of coming into contact with the conduction portion 62 of the mounting body 6 in holding the mounting body 6 is held, the conduction between the body 10 and the mounting body 6 may be secured more stably compared to a case where the holding member 2A does not have conductivity.

Moreover, in the holding mechanism 1A, in a case where the holding portion 21 is at the non-holding position Pf as described above, another part of the elastic member 4A is disposed so as to be present between the holding portion 21 at the non-holding position Pf and the body 10.

For this reason, according to the holding mechanism 1A, as illustrated in FIG. 3A and3B, in a case where the strut portion 22 of the holding member 2A is attached to the attachment hole 13 of the holding member 2A in the body 10 in a state in which a gap Gp is present and the holding member 2A is attached so as to slightly rock with respect to the body 10 in a case where the elastic member 4A is not present, the holding member 2A including the holding portion 21 is supported by the elastic member 4A at the non-holding position Pf. As a result, the holding member 2A may maintain the holding member 2A in a stable posture without rocking on the body 10 and being brought into an unstable state even in a case where the holding portion 21 is at the non-holding position Pf. Accordingly, the operation of rotating the holding member 2A may be easily performed.

### Removal of Mounting Body

Additionally, in the holding mechanism 1A, the removal of the mounting body 6 from the body 10 is performed as follows.

First, in the holding mechanism 1A, the holding member 2A is rotated to displace the holding portion 21 from the holding position Ph to the non-holding position Pf as shown in FIGS. 5A and 5B and FIGS. 7A and 7B. In this case, the operation of the displacement to the non-holding position Pf is also performed by manual work.

Accordingly, in the holding mechanism 1A, as shown in FIGS. 2A to 2C, the holding surface 21a of the holding portion 21 of the holding member 2A is displaced to the non-holding position Pf away from the contact with the end part 63 of the mounting body 6.

As a result, the end part 63 of the mounting body 6 having the conduction portion 62 is released from the holding state caused by the holding mechanism 1A. Additionally, in this case, the mounting body 6 receives a restoring force from the elastic member 4A that has been elastically deformed, and as illustrated by the two-dot chain line in FIG. 7A, the end part 63 having the conduction portion 62 thereof is slightly pushed upward (in the direction indicated by an arrow G2) so as to move away from the body 10.

Subsequently, the mounting body 6 pulls out the insertion end part 64 from the mounting portion 15.

Accordingly, the mounting body 6 is completely removed from the body 10 as illustrated in FIG. 4A.

More Detailed Configuration in Holding Mechanism

As shown in FIG. 3A, FIGS. 4A and 4B, FIGS. 5A and 5B, FIGS. 8A and 8B, and the like, the holding member 2A in the holding mechanism 1A has a displacement guide portion 25 that comes into contact with the end part 63 of the mounting body 6 while moving so as to approach the body 10 in a case where the end part 63 is held and guides the holding portion 21 in the process of being displaced to the non-holding position Pf to be displaced toward the non-holding position Pf.

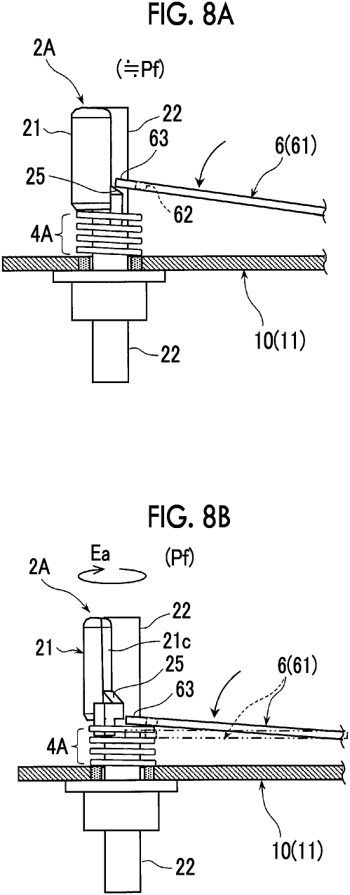

As shown in FIGS. 6A and 6B, FIGS. 8A and 8B, and the like, the displacement guide portion 25 in Exemplary Embodiment 1 is provided as an inclined surface portion that is inclined downward in a state in which the displacement guide portion is adjacent to the strut portion 22 at a lower portion of the back surface 21c on one side, which protrudes from the strut portion 22 of the holding portion 21.

The back surface 21c is a flat side surface of the holding portion 21 that protrudes from the strut portion 22. In other words, the back surface 21c is a surface portion of the holding portion 21 at the holding position Ph, which is located on a side not facing the mounting portion 15 of the body 10.

Additionally, the inclined surface portion of the displacement guide portion 25 is formed as a portion having an inclined surface that is inclined downward at a required angle so as to gradually move away from the mounting portion 15 on the back surface 21c of the holding portion 21 at the holding position Ph.

In the holding mechanism 1A comprising the holding member 2A having the displacement guide portion 25, as illustrated in FIG. 8A, even in a case where the holding portion 21 of the holding member 2A is held at a halfway position between the holding position Ph and the non-holding position Pf in the process of mounting the mounting body 6 (particularly in a case where a position slightly in front of the non-holding position Pf), the displacement guide portion 25 functions as follows.

That is, in this case, in the holding mechanism 1A, as compared to a case where the holding member 2A does not have the displacement guide portion 25, as illustrated in FIG. 8B, the end part 63 of the mounting body 6 may move downward while touching the inclined surface of the displacement guide portion 25 in conjunction with the pushing operation in a case where the mounting body 6 is mounted on the body 10, thereby inducing the rotation of the holding member 2A in the direction indicated by an arrow, and thus displacing the holding portion 21 toward the non-holding position Pf.

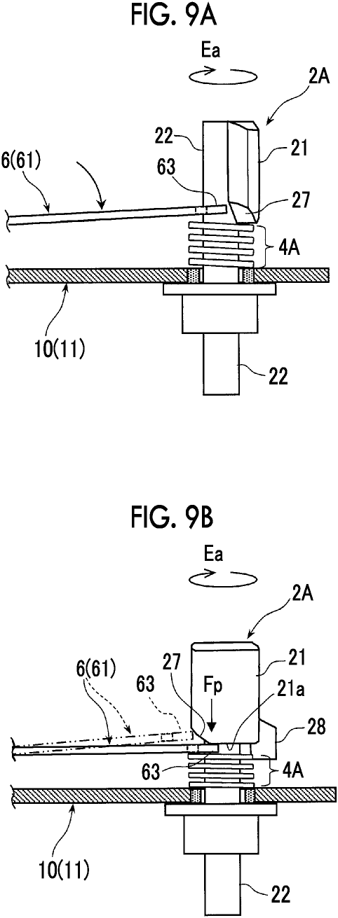

Additionally, as shown in FIG. 3B, FIG. 7B, FIGS. 9A and 9B, and the like, the holding member 2A in the holding mechanism 1A has a pressing guide portion 27 that comes into contact with the end part 63 of the mounting body 6 to guide the end part 63 to be pressed against the elastic member 4A, in a case where the holding portion 21 is rotated and displaced from the non-holding position Pf to the holding position Ph.

As shown in FIGS. 6A and 6B and the like, the pressing guide portion 27 in Exemplary Embodiment 1 is provided as an inclined surface portion that is inclined downward to reach the holding surface 21a at one corner portion at the lower portion of the holding portion 21 so as to remove the corner portion.

Additionally, in a case where the displacement guide portion 25 or a restraining portion 28 described below is provided, the pressing guide portion 27 is provided at a lower corner portion located opposite to the displacement guide portion 25 or the restraining portion 28 across the strut portion 22.

Moreover, an inclined surface is formed, which is inclined downward at a required angle, using the position of the holding portion 21, which is separated by a required distance in a height direction (a direction away from the body 10) from the holding surface 21a, as a starting point is formed at the inclined surface portion of the pressing guide portion 27. Additionally, the inclined surface is a surface formed with a width corresponding to the protrusion amount m1 (refer to FIG. 6B) from the strut portion 22 of the holding portion 21.

In the holding mechanism 1A comprising the holding member 2A having the pressing guide portion 27, as illustrated in FIG. 9A, in a case where the holding member 2A has been rotated so as to displace the holding portion 21 from the non-holding position Pf to the holding position Ph in the final process of mounting the mounting body 6, the pressing guide portion 27 functions as follows.

That is, first, as illustrated by the two-dot chain line in FIG. 9B, (the inclined surface portion of) the pressing guide portion 27 comes into contact with the end part 63 of the mounting body that has approached the elastic member 4A by rotating the holding member 2A in the direction indicated by the arrow Ea. At this point of time, the end part 63 of the mounting body 6 is temporarily landed in a temporary holding state.

Subsequently, the pressing guide portion 27 moves the end part 63 of the mounting body 6 coming into contact with the inclined surface portion thereof downward so as to be pressed against the elastic member 4A below the end part with a force Fp by continuing the rotation of the holding member 2A. Accordingly, the elastic member 4A is elastically deformed so as to be compressed in conjunction with the rotational operation of the holding member 2A.

Finally, in a case where the holding member 2A is further rotated and the contact of the inclined surface portion of the pressing guide portion 27 with the end part 63 of the mounting body 6 is completed by passing, as shown by a solid line in FIG. 9B, the holding surface 21a of the holding portion 21 is brought into a state of riding on the end part 63 of the mounting body 6. Accordingly, the end part 63 of the mounting body 6 is brought into a state of having been sandwiched and held between the holding surface 21a of the holding portion 21 and the elastic member 4A.

Therefore, in the holding mechanism 1A having the pressing guide portion 27, a state in which the elastic member 4A may be elastically deformed and held in conjunction with the operation in a case where the mounting body 6 is mounted on the body 10 may be brought about as compared to a case where the holding member 2A does not have the pressing guide portion 27.

Additionally, in a case where the pressing guide portion 27 is provided, it is not necessary to perform the operation of pushing down the mounting body 6 with hands to elastically deform the elastic member 4A in the process of mounting the mounting body 6, and the elastic deformation of the elastic member 4A can be performed in conjunction with the rotational operation of the holding member 2A.

Moreover, as shown in FIG. 3B, FIG. 7B, FIGS. 9A and 9B, and the like, the holding member 2A in the holding mechanism 1A has the restraining portion 28 that comes into contact with a part of the mounting body 6 to restrain the displacement of the holding portion 21 in a case where the holding portion 21 has been displaced from the non-holding position Pf to the holding position Ph.

As shown in FIGS. 6A and 6B, and the like, the restraining portion 28 in Exemplary Embodiment 1 is provided as a protruding portion that protrudes in the direction of a radius r from the strut portion 22 at the lower portion of the back surface 21c on one side, which protrudes from the strut portion 22 of the holding portion 21.

In the case of the protruding portion, a portion (surface portion) located on a side where the holding portion 21 is present is configured as a portion that actually comes into contact with a part (an end part where the end part 63 is present) of the mounting body 6. Additionally, in a case where the displacement guide portion 25 is provided, the restraining portion 28 is provided so as to be present on the lower side of the displacement guide portion 25. Additionally, in a case where the pressing guide portion 27 is provided, the restraining portion 28 is provided so as to be present at a position opposite to the pressing guide portion 27 across the strut portion 22.

In the holding mechanism 1A comprising the holding member 2A having the restraining portion 28, as shown in FIGS. 2A to 2C, FIGS. 3A and 3B, FIGS. 5A and 5B, and the like, in a case where the holding member 2A is rotated so as to displace the holding portion 21 from the holding position Pf to the non-holding position Pf in the final process of mounting the mounting body 6, the restraining portion 28 functions as follows.

That is, in the process of mounting the mounting body 6, as shown in FIGS. 5A and 5B, the restraining portion 28 is present at a position where the restraining portion does not come into contact with the mounting body 6 in a case where the holding portion 21 of the holding member 2A is displaced to the non-holding position Pf. Subsequently, in a case where the holding member 2A is rotated in the direction of the arrow Ea such that the holding portion 21 is displaced from the non-holding position Pf to the holding position Ph, the restraining portion 28 moves integrally with the holding member 2A.

Finally, as shown in FIG. 2A and FIG. 3A, the restraining portion 28 comes into contact with the end part of the mounting body 6 where the end part 63 is present. Accordingly, at the same time that the rotation of the holding member 2A in the direction of the arrow Ea is stopped, the displacement of the holding portion 21 is restrained. As a result, the holding member 2A is brought into a state in which the holding portion 21 has been stopped at the holding position Ph.

Therefore, in the holding mechanism 1A having the restraining portion 28, as compared to a case where the holding member 2A does not have the restraining portion 28, the holding portion 21 is accurately displaced to the holding position Ph and stopped in a case where the mounting body 6 is mounted on the body 10.

### Modification Example of Exemplary Embodiment 1

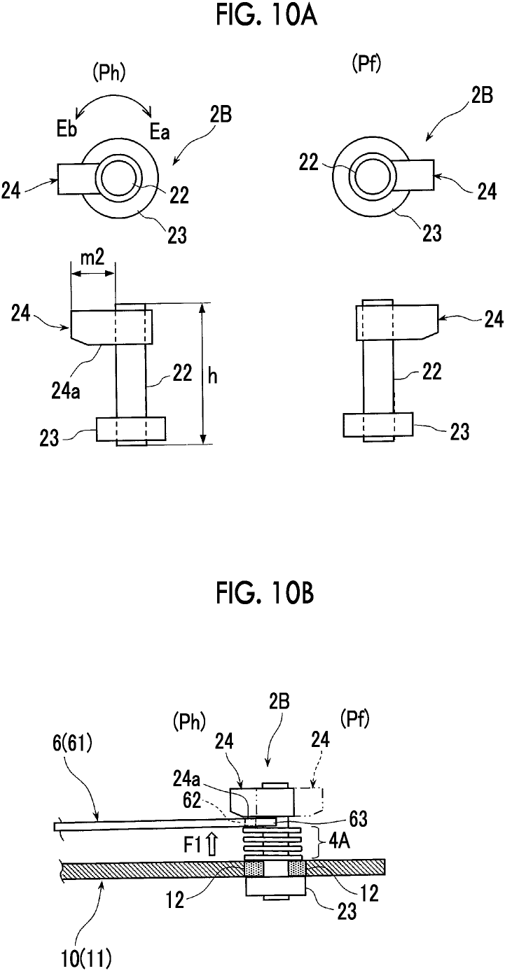

As the holding mechanism 1A, a holding member 2B as shown in FIGS. 10A and 10B may be applied instead of the holding member 2A.

The holding member 2B is different in that the holding portion 24 is provided so as to rotate with respect to the strut portion 22 fixed to the body 10, but except for that the holding member 2B is configured similar to the holding member 2A.

The holding portion 24 is attached so as to rotate in the direction indicated by the arrows Ea and Eb at a predetermined position at an upper portion of the strut portion 22, so that the holding portion 24 can be displaced between the holding position Ph and the non-holding position Pf.

As shown in FIG. 10A, the holding portion 24 is configured as a portion consisting of a shape protruding outward by a required protrusion amount m2 from a part of the upper side surface of the strut portion 22. Additionally, as shown in FIG. 10B, the holding portion 24 has a holding surface 24a that faces the surface of the body 10 at a spacing and consists of a face substantially parallel to the surface of the body 10. The holding surface 24a is displaced to the holding position Ph in a case where the mounting body 6 is mounted, and comes into contact with the end part 63 of the mounting body 6.

As shown in FIG. 10B, the holding member 2B having the holding portion 24 is provided by inserting the lower portion of the strut portion 22 into the attachment hole 13 provided in the body 10 to pass a part thereof through the attachment hole, and then attaching a spacing maintaining portion 23 to a portion of the strut portion 22 protruding from the attachment hole 13.

In this case, in the holding member 2B, the lower portion of the strut portion 22 is fitted into the attachment hole 13 in the body 10 with almost no gap. Accordingly, the holding member 2B is provided in a state of being fixed to the body 10 via the lower portion of the strut portion 22.

In a case where the mounting body 6 is mounted and held, the holding mechanism 1A comprising the holding member 2B rotates the holding portion 24 of the holding member 2B around the strut portion 22 (as an axis) to displace the holding portion 24 to the non-holding position Pf, then inserting the mounting body 6 into the mounting portion 15, then pressing the end part 63 of the mounting body 6 against the elastic member 4A, and then displacing the holding portion 24 to the holding position Ph.

Accordingly, as shown in FIG. 10B, the holding mechanism 1A interposes and holds the end part 63 of the mounting body 6 including the conduction portion 62 at the end part 63 between the holding portion 24 at the holding position Ph of the holding member 2A and the elastic member 4A in the elastically deformed state.

Additionally, in a case where the mounting body 6 is removed from the body 10, the holding mechanism 1A rotates the holding portion 24 of the holding member 2B around the strut portion 22 (as an axis) to displace the holding portion from the holding position Ph to the non-holding position Pf, and releases the holding state of the end part 63 of the mounting body 6. After that, the mounting body 6 is pulled out from the mounting portion 15. Accordingly, the mounting body 6 is removed from the body 10.

### Exemplary Embodiment 2

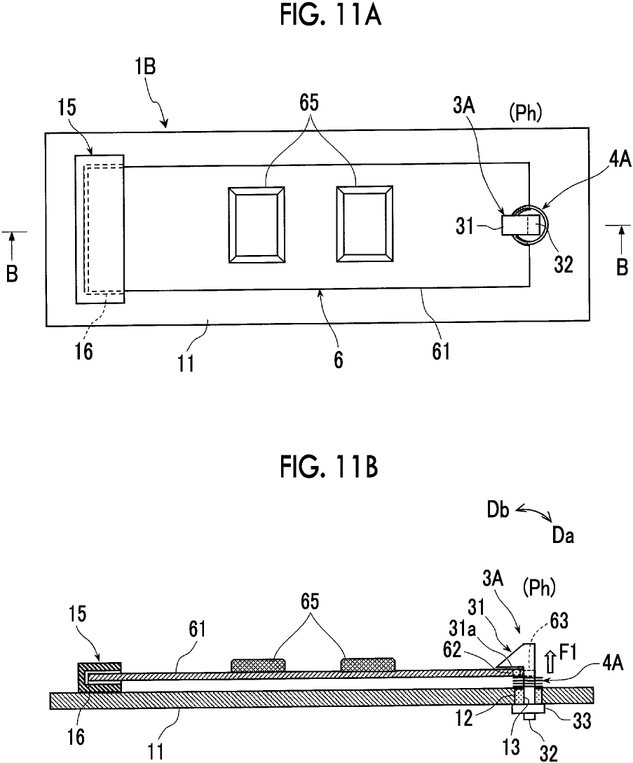

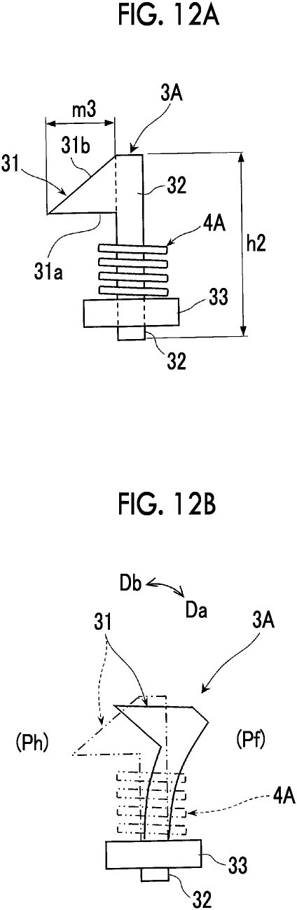

FIGS. 11A and 11B and FIGS. 12A and 12B are plan views and partial cross-sectional views showing a holding mechanism 1B according to Exemplary Embodiment 2 of the present invention.

The holding mechanism 1B is different in that a holding member 3A is applied instead of the holding member 2A, but except for that, the holding mechanism 1B consists of the same configuration as the holding mechanism 1A according to Exemplary Embodiment 1.

For this reason, as shown in FIGS. 11A and 11B, and the like, the holding mechanism 1B includes the body 10, the holding member 3A, and an elastic member 4A.

The holding member 3A in Exemplary Embodiment 2 has a holding portion 31 that is displaced between a holding position Ph where the holding member comes into contact with and holds the end part 63 of the mounting body 6 and a non-holding position Pf where the holding member 3A does not hold the end part 63, and a holding portion 31, and an elastic strut portion 32 that supports the holding portion 31.

The holding portion 31 is a portion capable of at least coming into contact with and holding the end part 63 having the conduction portion 62 of the mounting body 6 mounted on the body 10. As shown in FIG. 12A, the holding portion 31 is configured as, for example, a portion consisting of a shape protruding outward by a required protrusion amount m3 from a part of an upper side surface of the strut portion 32.

Additionally, as shown in FIG. 11B, the holding portion 31 has a holding surface 31a that faces the surface of the body 10 at a spacing and consists of a face substantially parallel to the surface of the body 10. The holding surface 31a is displaced to the holding position Ph in a case where the mounting body 6 is mounted, and comes into contact with the end part 63 of the mounting body 6.

Moreover, an inclined surface 31b, which is inclined downward with respect to the protruding direction, is formed on an upper portion of the holding portion 31.

Such a holding portion 31 is provided in a state of being integrally molded with and fixed to the strut portion 32, or is provided by fixing a body formed separately from the strut portion 32 to the strut portion 32. The strut portion 32 is formed of a material having elasticity.

The strut portion 32 is a portion having elasticity that supports the holding portion 31 and can be elastically deformed in a case where the strut portion has received an external force. As shown in FIG. 12A, the strut portion 32 is constituted of, for example, a prismatic member consisting of a required length h2. As shown in FIG. 12B, the strut portion 32 is elastically deformed in directions indicated by arrows Da and Db, thereby supporting the holding portion 31 so as to be displaced between the holding position Ph and the non-holding position Pf. In addition, the strut portion 32 may have, for example, a columnar shape with respect to a portion below the holding portion 31.

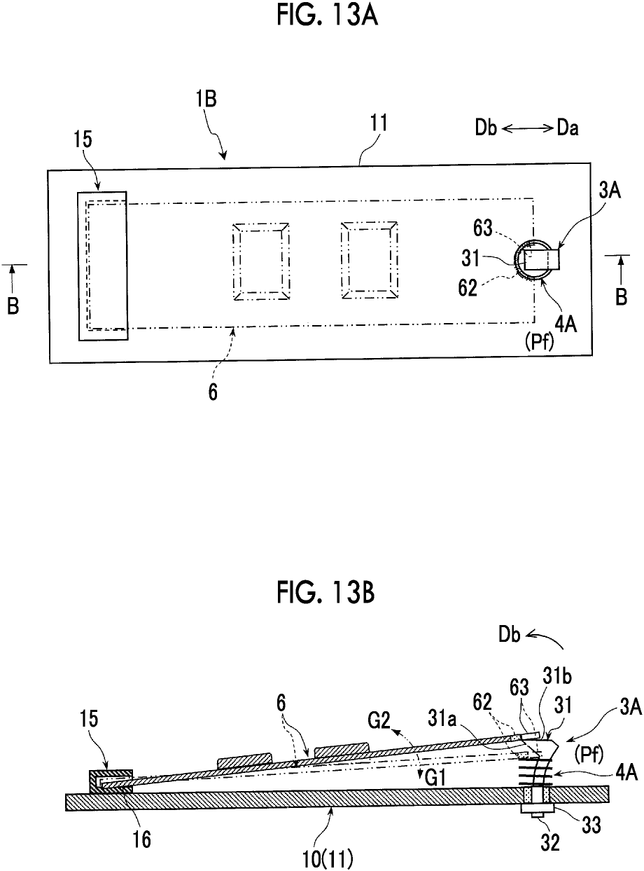

Additionally, as shown in FIGS. 11A and 11B, FIGS. 13A and 13B, and the like, the holding member 3A is disposed such that the strut portion 32 thereof is present in the coil of the conductive elastic member 4A consisting of a coil spring and the holding portion 31 is present above the coil spring.

Additionally, the holding member 3A is configured as a member to which conductivity is given or configured as a non-conductive member. The holding member 3A in Exemplary Embodiment 2 is configured as a non-conductive member.

Moreover, the holding member 3A is provided on the body 10 as follows, for example.

That is, as shown in FIG. 11B and FIG. 13B, the holding member 3A is provided by inserting a lower portion of the strut portion 32 into the attachment hole 13 provided in the body 10 to pass a part thereof through the attachment hole, and then attaching a spacing maintaining portion 33 to a portion (a portion present on a side opposite to the holding portion 31 across the body 10) of the strut portion 32 protruding from the attachment hole 13.

In this case, the holding member 3A is provided in such a posture that the holding portion 31 faces the mounting portion 15. Additionally, in this case, in the holding member 3A, the lower portion of the strut portion 32 is fitted into the attachment hole 13 in the body 10 with almost no gap. Accordingly, the holding member 3A is provided in a state of being fixed to the body 10 via the lower portion of the strut portion 32. In this case, the lower portion of the strut portion 32 is provided in a state of having come into contact with the conduction portion 12 provided around the attachment hole 13, but may be provided in a state of not coming into contact with the conduction portion 12.

### Mounting and Holding of Mounting Body

In the holding mechanism 1B consisting of the above configuration, the mounting body 6 is mounted and held as follows.

First, in the holding mechanism 1B, as shown in FIGS. 13A and 13B, the holding portion 31 of the holding member 3A is displaced so as to be present at the non-holding position Pf. The operation of the displacement to the non-holding position Pf is performed by manual work. The manual work is a work of pinching the holding portion 31 of the holding member 3A with fingers and moving the holding portion in the direction indicated by the arrow Da.

In this case, in the holding member 3A, the portion of the elastic strut portion 32 exposed onto the body 10 is elastically deformed so as to be curved in the direction indicated by the arrow Da. The state of displacement of the holding portion 31 to the non-holding position Pf is maintained by the manual work until immediately before the end part 63 of the mounting body 6 is held.

Accordingly, in the holding mechanism 1B, the holding portion 31 of the holding member 3A is brought into a state of being not present at the holding position Ph. In this case, as shown in FIGS. 13A and 13B, the holding member 3A elastically deforms the strut portion 32 until the holding member is displaced to the non-holding position Pf where the holding member does not interfere with the movement path of the end part 63 of the mounting body 6 in a case where the holding portion 31 is mounted.

Additionally, in this case, due to the displacement of the holding portion 31 to the non-holding position Pf, in the holding mechanism 1A, as shown in FIG. 13B, a part of the elastic member 4A (particularly a part of the upper end of the coil spring) hidden from above by the holding portion 31 at the holding position Ph is brought into a state of having been exposed upward toward the lateral side of the strut portion 32.

In addition, in the holding mechanism 1B, in a case where there may be a concern that the elastic member 4A of the coil spring may be separated from the holding member 3A in a case where the holding portion 31 of the holding member 3A has been displaced to the non-holding position Pf, or in a case where there may be a concern that the position of the elastic member 4A may be shifted and a part of the elastic member 4A may be exposed as described above, the elastic member 4A (one end part) may be configured to be restricted in position with respect to the body 10, for example.

Subsequently, with respect to the mounting body 6 to be mounted, as illustrated by two-dot chain lines in FIG. 13B, the insertion end part 64 is inserted into the insertion recess 16 of the mounting portion 15 in the body 10 to be in a slightly inclined state, and then, a portion on a side with the end part 63 having the conduction portion 62 is moved in the direction indicated by then arrow G1 so as to approach the holding member 3A of the body 10.

In addition, the above operation of displacement of the holding portion 31 of the holding member 3A to the non-holding position Pf may be performed in cooperation with the operation in a case where the mounting body 6 is mounted on the mounting portion 15 and moved in the direction indicated by the arrow G1.

Additionally, the holding member 3A has the inclined surface 31b that is inclined downward in a direction protruding to an upper portion of the holding portion 31. For this reason, in the holding member 3A, as long as the elastic restoring force of the strut portion 32 is relatively small, as illustrated by the solid line in FIG. 13B, it is possible to elastically deform the strut portion 32 to displace the holding portion 31 the non-holding position Pf by moving the mounting body 6 downward in the direction indicated by the arrow G1 in a state in which the end part 63 has been made to come into contact with the inclined surface 31b in conjunction with the mounting operation of the mounting body 6.

Subsequently, in the holding mechanism 1B, in a case where the elastic member 4A is deformed so as to be compressed by moving the mounting body 6 downward in the direction indicated by the arrow G1 after the end part 63 of the mounting body 6 has come into contact with the conductive elastic member 4A, and in a case where the end part 63 has passed through a protruding tip of the holding portion 31 at the non-holding position Pf of the holding member 3A, the holding portion 31 displaced to the non-holding position Pf by the manual work is released.

Accordingly, the holding member 3A moves such that the strut portion 32 moves in the direction indicated by the arrow Db due to the restoring force caused by the elastic deformation and returns to a posture substantially perpendicular to the body 10. As a result, the holding portion 31 is displaced so as to return from the non-holding position Pf to the holding position Ph.

Additionally, in this case, in the holding member 3A, the holding surface 31a of the holding portion 31 that is displaced so as to return to the holding position Ph comes into contact with the end part 63 of the mounting body 6, which presses the elastic member 4A so as to elastically deform the elastic member 4A, including the conduction portion 62.

As a result, the mounting body 6 is mounted on the body 10 as shown in FIGS. 11A and 11B.

Additionally, in this case, as shown in FIG. 11B, the holding mechanism 1B sandwiches and holds the end part 63 of the mounting body 6 including the conduction portion 62 at the end part 63 between the holding portion 31 at the holding position Ph of the holding member 3A and the elastic member 4A in the elastically deformed state.

Additionally, as shown in FIG. 11B, the mounting body 6 held by the holding mechanism 1B is mounted on the body 10 in a state in which the entire mounting body (printed board 61) is substantially parallel to the surface of the body 10.

Then, as shown in FIG. 11B, and the like, the elastic member 4A in the elastically deformed state in a case where the elastic member is held is brought into a state in which at least a part of the lower end part thereof is brought into a state of having come into contact with a part of the conduction portion 12 of the body 10, while at least a part of the upper end part thereof is brought into a state of having come into contact with a part of the conduction portion 62 of the mounting body 6.

Accordingly, the mounting body 6 is brought into a state in which the mounting body 6 and the body 10 are connected to each other in an energizable manner via the conduction portion 62, the conductive elastic member 4A, and the conduction portion 12.

Additionally, as shown in FIG. 11B, the end part 63 of the mounted mounting body 6 including the conduction portion 62 receives the force F1 caused by the restoring force of the elastic member 4A after elastic deformation, and is maintained in the state of being elastically pressed toward (the holding surface 31a of) the holding portion 31 of the holding member 3A.

Therefore, according to the holding mechanism 1B, the conductive elastic member 4A in the elastically deformed state connects the conduction portion 12 and the conduction portion 62 to each other in a conductable manner, and elastically presses the end part 63 of the mounting body 6 against the holding portion 31 of the holding member 3A. Thus, the conduction between the body 10 and the mounting body 6 is stable even in a case where vibration is received.

### Removal of Mounting Body

Additionally, in the holding mechanism 1B, the removal of the mounting body 6 from the body 10 is performed as follows.

First, in the holding mechanism 1B, the holding portion 31 at the holding position Ph of the holding member 3A is displaced so as to be present at the non-holding position Pf. The operation of the displacement to the non-holding position Pf is performed by manual work.

Accordingly, in the holding mechanism 1B, as shown in FIG. 13B, the holding surface 31a of the holding portion 31 of the holding member 3A is displaced to the non-holding position Pf away from the contact with the end part 63 of the mounting body 6.

As a result, the end part 63 of the mounting body 6 having the conduction portion 62 is released from the holding state caused by the holding mechanism 1B. Additionally, in this case, the mounting body 6 receives a restoring force from the elastic member 4A that has been elastically deformed, and as illustrated by the two-dot chain line in FIG. 13B, the end part 63 having the conduction portion 62 thereof is slightly pushed upward (in the direction indicated by the arrow G2) so as to move away from the body 10.

Subsequently, the mounting body 6 pulls out the insertion end part 64 from the mounting portion 15.

Accordingly, the mounting body 6 is completely removed from the body 10.

### Modification Example of Exemplary Embodiment 2

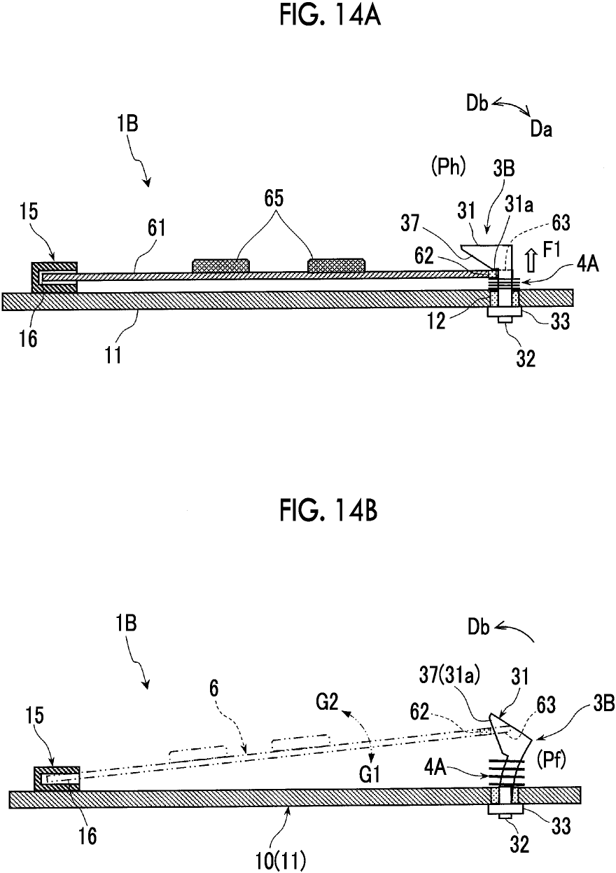

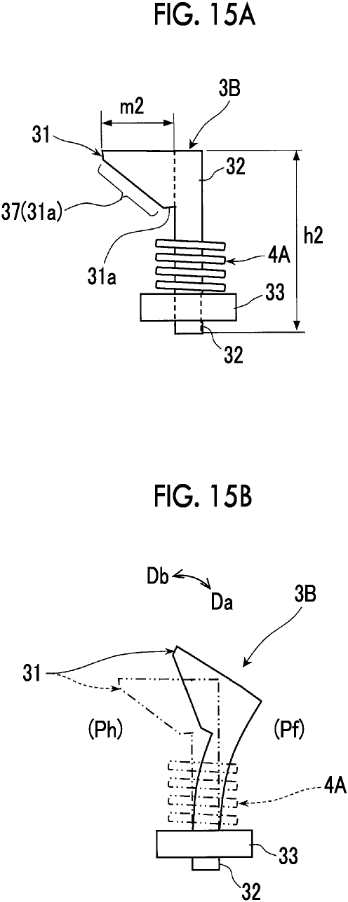

In the holding mechanism 1B, a holding member 3B as shown in FIGS. 14A and 14B and FIGS. 15A and 15B may be applied instead of the holding member 3A.

The holding member 3B is different in that the holding portion 31 has a pressing guide portion 37 instead of the inclined surface 31b, but except for that, the holding member 3B is configured similar to the holding member 3A.

As shown in FIG. 14B and FIG. 15A, the pressing guide portion 37 is a portion that comes into contact with the end part 63 of the mounting body 6 to guide the end part 63 to be pressed against the elastic member 4A in a case where the strut portion 32 of the holding member 3B is restored after elastic deformation and the holding portion 31 is displaced from the non-holding position Pf to the holding position Ph. The pressing guide portion 37 is configured as an inclined surface portion that is inclined at a required angle so as to reach the holding surface 31a from a protruding tip part of the holding portion 31 of the holding member 3B.

The pressing guide portion 37 may function as a part of the holding surface 31a on a part on the lower side thereof.

In the holding mechanism 1B comprising the holding member 3B having the pressing guide portion 37, the operation of a mounting process described below is partially different, but except for that, almost the same mounting and holding as the mounting and holding of the mounting body 6 in Exemplary Embodiment 2 are performed.

The operation of the different mounting process is performed in a case where the holding portion 31 displaced to the non-holding position Pf by the manual work has been released, in a state in which the end part 63 of the mounting body 6 has faced the pressing guide portion 37 of the holding portion 31 of the holding member 3B.

That is, in this case, in the holding member 3B, as shown in FIGS. 15 and 15B, the holding portion 31 is displaced from the non-holding position Pf to the holding position Ph. For this reason, in the holding mechanism 1B, as illustrated by the two-dot chain line in FIG. 14B, the end part 63 of the mounting body 6 is moved in the direction indicated by the arrow G1 by being pressed downward by the inclined surface portion of the pressing guide portion 37 in the holding portion 31 that moves toward the holding position Ph, and finally comes into contact with the portion of the coil spring of the elastic member 4A that is exposed toward the upper side of the upper end part.

Additionally, in this case, the end part 63 of the mounting body 6 after having come into contact with the elastic member 4A is pressed downward by the inclined surface portion of the pressing guide portion 37 in the holding portion 31 that continues moving toward the holding position Ph, and is moved in the direction indicated by the arrow G1. Accordingly, as shown in FIG. 14A, the coil spring of the elastic member 4A is elastically deformed so as to be compressed by being pushed by the end part 63 thereof.

In addition, as shown in FIG. 14A, finally, the holding mechanism 1B of this modification example interposes and holds the end part 63 of the mounting body 6 including the conduction portion 62 at the end part 63 between the holding portion 31 at the holding position Ph of the holding member 3B and the elastic member 4A in the elastically deformed state.

### Exemplary Embodiment 3

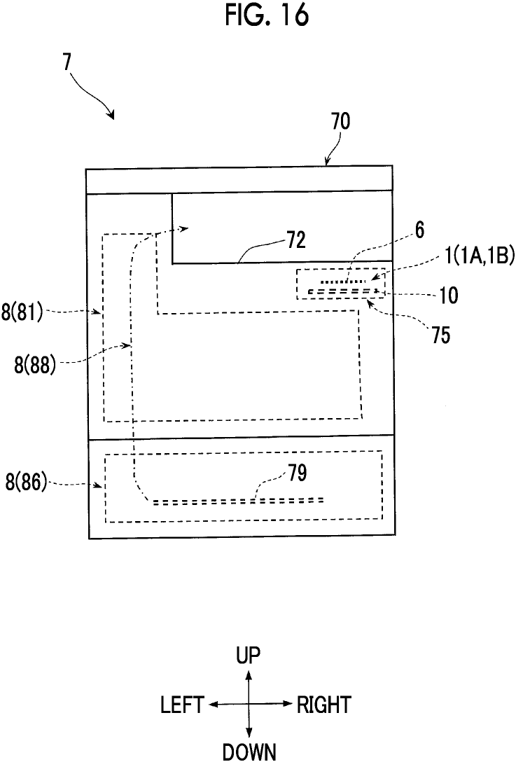

FIG. 16 is a schematic view of a device 7 comprising the holding mechanism 1 according to Exemplary Embodiment 3 of the present invention.

The device 7 comprising the holding mechanism 1 has a housing 70, an image forming unit 81 as an example of an operating unit 8, a medium supply unit 86 of a recording medium 79, and a medium transport unit 88 are disposed in the housing 70, and a control unit 75 that controls the operation of the operating unit 8 and the like is disposed in the housing.

For this reason, the device 7 according to Exemplary Embodiment 3 is configured as an image forming device that forms an image, based on image information input from the outside, on the recording medium 79.

The image forming unit 81 is a portion that actually forms an image on the recording medium 79. The image forming unit 81 is constituted of equipment corresponding to a required image forming method such as an electrophotographic method, an ink jet method, an electrostatic recording method, a heat sensitive recording method, and related equipment.

The medium supply unit 86 is a portion that accommodates and supplies the recording medium 79 used in the image forming unit 81. The medium supply unit 86 includes an accommodating body that accommodates a plurality of recording media 79, a delivery device that delivers the recording medium 79 accommodated in the accommodating body to the medium transport unit 88, and the like. The recording medium 79 may be any medium as long as an image can be formed thereon by the image forming unit 81 and the medium can be transported by the medium transport unit 88.

The medium transport unit 88 is a portion that transports the recording medium 79 delivered from the medium supply unit 86 to the image forming unit 81, and transports the recording medium 79 on which the image is formed by the image forming unit 81 to the medium ejection unit 72 provided in the housing 70 so as to eject the recording medium 79. The medium transport unit 88 is constituted of a plurality of transport rolls that transports the recording medium 79, a guide member that transports and guides the recording medium 79, and the like.

The control unit 75 is constituted of equipment necessary for control operation (including equipment necessary for detection). The control unit 75 in Exemplary Embodiment 3 comprises the body 10 consisting of, for example, an electronic circuit board or the like, and the mounting body 6 such as a memory mounting board mounted on the body 10.

Similar to the case of, for example, the body 10 in Exemplary Embodiment 1 or the like (refer to FIG. 1, FIGS. 2A to 2C, FIGS. 4A and 4B, or the like), the body 10 has the conduction portion 12 and the mounting portion 15 on which the mounting body 6 is mounted.

Similar to the case of, for example, the mounting body 6 in Exemplary Embodiment 1 (refer to FIG. 1, FIGS. 2A to 2C, FIGS. 4A and 4B, or the like), the mounting body 6 has the end part 63 provided with the conduction portion 62 capable of facing the conduction portion 12 of the body 10, and the insertion end part 64 that is inserted into and mounted on the mounting portion 15.

Additionally, similar to the case of the body 10 in Exemplary Embodiment 1 or the like, the body 10 comprises the holding mechanism 1 that holds the end part 63 of the mounting body 6 mounted on the mounting portion 15 so as to enable the conduction between the body 10 and the mounting body via the conduction portion 62 and the conduction portion 12.

Also, a part or all of the holding mechanism 1 is constituted of the holding mechanism 1A (refer to FIG. 1 to FIG. 4B, and the like) according to Exemplary Embodiment 1 (including the modification example thereof), or the holding mechanism 1B (refer to FIG. 11A to FIG. 13B, and the like) according to Exemplary Embodiment 2 (including the modification example thereof).

Accordingly, in the control unit 75, in a case where the mounting body 6 is mounted on the body 10, the end part 63 of the mounting body 6 is held by the holding mechanisms 1A and 1B.

On the other hand, in the device 7 consisting of an image forming device, for example, in a case where the timing to form an image is reached, the image forming unit 81, the medium supply unit 86, and the medium transport unit 88, which are the operating unit 8, operate and vibration is generated with the operation. The vibration may include vibration transmitted to the body 10 or the like of the control unit 75.

In this case, in a case where the body 10 or the like in the control unit 75 receives vibration associated with the operation, there may be a concern that the conduction between the body 10 and the mounting body 6 in the control unit 75 may become unstable.

In this respect, in the device 7, compared to a case where the holding mechanism 1 is not a mechanism that is interposed and held between holding portions 21, 31 such as the holding members 2A, 3A at the holding position Ph in the body 10, and the conductive elastic member 4A in the elastically deformed state, the conduction between the body 10 and the mounting body 6 is stable without being adversely affected by the vibration even in a case where the vibration transmitted from the operating unit 8 is received.

As a result, in the device 7, there is no concern that the conduction between the body 10 and the mounting body 6 in the control unit 75 becomes poor due to vibration and causes a malfunction, and a stable operation is performed.

### Others

The present invention has shown representative configuration examples according to Exemplary Embodiment 1 to Exemplary Embodiment 3 (including the modification examples thereof), but the present invention is not limited to these configurations, and some of the configurations may be changed as necessary.

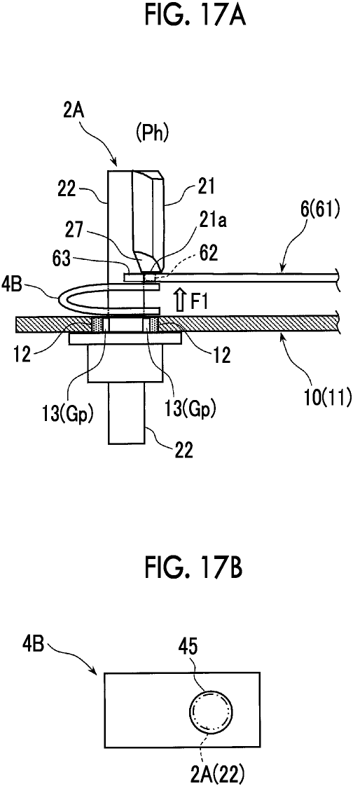

For example, the elastic member having conductivity is not limited to the elastic member 4A consisting of the coil spring, but an elastic member 4B made of a leaf spring having conductivity or the like may be applied as illustrated in FIG. 17A.

The elastic member 4B consisting of the leaf spring is, for example, a leaf spring that is bent in a U shape as shown in FIG. 17B or the like and provided with a through-hole 45 through which the strut portion 22 of the holding member 2A passes, and is used by being installed in a state in which the elastic member is laid down sideways.

Additionally, in a case where the elastic member 4B is applied, the holding member 2A may be provided in a state in which the strut portion 22 is passed through the through-hole 45.

Additionally, the body 10 is not limited to the body having the plate-shaped form and may be a body consisting of another form as long as the mounting body 6 is mounted in a conductable manner.

The mounting body 6 is also not limited to the mounting body consisting of the plate-shaped form and may be a mounting body having another form. The end part 63 provided with the conduction portion 62 of the mounting body 6 is not limited to the end part having the recessed shape and may be, for example, an end part consisting of a linearly extending shape or an end part having a protruding shape.

Additionally, in the holding mechanism 1 (1A, 1B), in a case where the mounting body 6 has a plurality of the end parts 63 provided with the conduction portions 62, the holding member 2 (2A, 3A, or the like) corresponding to some or all of the plurality of end parts 63 may be provided in the body 10.

The device 7 comprising the holding mechanism 1 is not limited to the image forming device and may be any device as long as the device has an operating unit that possibly transmits the vibration generated during operation to the body 10 or the like constituting the holding mechanism 1.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A holding mechanism comprising:
a body having a conduction portion, and a mounting portion on which a mounting body having an end part provided with a conduction portion capable of facing the conduction portion is mounted;
a holding member that is provided on the body and has a holding portion displaced between a holding position where the holding portion comes into contact with an end part of the mounting body to hold the end part and a non-holding position where the holding portion avoids the end part not to hold the end part; and
a conductive elastic member that is installed between at least the conduction portion of the body and the holding portion at least at the holding position,
wherein the end part of the mounting body, including the conduction portion at the end part, is interposed and held between the holding portion at the holding position and the elastic member in an elastically deformed state.

2. The holding mechanism according to claim 1,
wherein the holding member has a strut portion that supports the holding portion, and the holding portion is displaced between the holding position and the non-holding position by rotating around the strut portion.

3. The holding mechanism according to claim 1,
wherein the holding member has a displacement guide portion that comes into contact with the end part of the mounting body while moving so as to approach the body in a case where the end part is held and guides the holding portion in a process of being displaced to the non-holding position to be displaced toward the non-holding position.

4. The holding mechanism according to claim 1,
wherein the holding member has a pressing guide portion that comes into contact with the end part of the mounting body to guide the end part to be pressed against the elastic member, in a case where the holding portion is rotated and displaced from the non-holding position to the holding position.

5. The holding mechanism according to claim 1,
wherein the holding member has a restraining portion that comes into contact with a part of the mounting body to restrain displacement of the holding portion in a case where the holding portion has been displaced from the non-holding position to the holding position.

6. The holding mechanism according to claim 1,
wherein a part of the elastic member is installed so as to be present between the holding portion at the holding position and the body in a case where the holding portion is at the non-holding position.

7. The holding mechanism according to claim 2,
wherein the holding member is provided such that the holding portion is fixed to the strut portion, and the strut portion is rotatably attached to the body.

8. The holding mechanism according to claim 2,
wherein a part of the elastic member is installed so as to be present between the holding portion and the body in a case where the holding portion is at the non-holding position.

9. The holding mechanism according to claim 7,
wherein a part of the elastic member is installed so as to be present between the holding portion and the body in a case where the holding portion is at the non-holding position.

10. The holding mechanism according to claim 1,
wherein the holding member has an elastic strut portion that supports the holding portion, and the holding portion is displaced between the holding position and the non-holding position due to elastic deformation of the strut portion.

11. The holding mechanism according to claim 10,
wherein the holding member has a pressing guide portion that comes into contact with the end part of the mounting body to guide the end part to be pressed against the elastic member, in a case where the strut portion is restored after the elastic deformation and the holding portion is displaced from the non-holding position to the holding position.

12. The holding mechanism according to claim 1,
wherein the elastic member is a coil spring, and the holding member is present in a coil of the coil spring and is installed so that the holding portion is capable of coming into contact with a part of the coil spring.

13. A device comprising a holding mechanism including:
a body having a conduction portion, and a mounting portion on which a mounting body having an end part provided with a conduction portion capable of facing the conduction portion is mounted;
a holding mechanism that holds the mounting body on the body; and
an operating unit that possibly transmits vibration to the body,
wherein at least a part of the holding mechanism is constituted of the holding mechanism according to claim 1.

14. A device comprising a holding mechanism including:
a body having a conduction portion, and a mounting portion on which a mounting body having an end part provided with a conduction portion capable of facing the conduction portion is mounted;
a holding mechanism that holds the mounting body on the body; and
an operating unit that possibly transmits vibration to the body,
wherein at least a part of the holding mechanism is constituted of the holding mechanism according to claim 2.

15. A device comprising a holding mechanism including:
a body having a conduction portion, and a mounting portion on which a mounting body having an end part provided with a conduction portion capable of facing the conduction portion is mounted;
a holding mechanism that holds the mounting body on the body; and
an operating unit that possibly transmits vibration to the body,
wherein at least a part of the holding mechanism is constituted of the holding mechanism according to claim 3.

16. A device comprising a holding mechanism including:
a body having a conduction portion, and a mounting portion on which a mounting body having an end part provided with a conduction portion capable of facing the conduction portion is mounted;
a holding mechanism that holds the mounting body on the body; and
an operating unit that possibly transmits vibration to the body,
wherein at least a part of the holding mechanism is constituted of the holding mechanism according to claim 4.

17. A device comprising a holding mechanism including:
a body having a conduction portion, and a mounting portion on which a mounting body having an end part provided with a conduction portion capable of facing the conduction portion is mounted;
a holding mechanism that holds the mounting body on the body; and
an operating unit that possibly transmits vibration to the body,
wherein at least a part of the holding mechanism is constituted of the holding mechanism according to claim 5.

18. A device comprising a holding mechanism including:
a body having a conduction portion, and a mounting portion on which a mounting body having an end part provided with a conduction portion capable of facing the conduction portion is mounted;
a holding mechanism that holds the mounting body on the body; and
an operating unit that possibly transmits vibration to the body,
wherein at least a part of the holding mechanism is constituted of the holding mechanism according to claim 6.

19. A device comprising a holding mechanism including:
a body having a conduction portion, and a mounting portion on which a mounting body having an end part provided with a conduction portion capable of facing the conduction portion is mounted;
a holding mechanism that holds the mounting body on the body; and
an operating unit that possibly transmits vibration to the body,
wherein at least a part of the holding mechanism is constituted of the holding mechanism according to claim 7.

20. A device comprising a holding mechanism including:
a body having a conduction portion, and a mounting portion on which a mounting body having an end part provided with a conduction portion capable of facing the conduction portion is mounted;
a holding mechanism that holds the mounting body on the body; and
an operating unit that possibly transmits vibration to the body,
wherein at least a part of the holding mechanism is constituted of the holding mechanism according to claim 8.
